(19) United States
(12) Patent Application Publication
(10) Pub. No.: US 2024/0038779 A1
(43) Pub. Date: Feb. 1, 2024

(54) DISPLAY PANEL, DISPLAY DEVICE, AND MANUFACTURING METHOD OF DISPLAY PANEL

(71) Applicant: TCL CHINA STAR OPTOELECTRONICS TECHNOLOGY CO., LTD., Shenzhen, Guangdong (CN)

(72) Inventor: Yong Deng, Shenzhen, Guangdong (CN)

(73) Assignee: TCL CHINA STAR OPTOELECTRONICS TECHNOLOGY CO., LTD., Shenzhen, Guangdong (CN)

(21) Appl. No.: 17/597,942

(22) PCT Filed: Jan. 11, 2022
(86) PCT No.: PCT/CN2022/071250

§ 371 Date: Jul. 6, 2023

(30) Foreign Application Priority Data
Dec. 28, 2021 (CN) 202111629034.3

(51) Int. Cl. H01L 27/12

(52) U.S. Cl. CPC H01L 27/1244; H01L 27/1292

(57) ABSTRACT

The present application provides a display panel, a display device, and a manufacturing method of the display panel. The display panel includes a substrate, a first terminal, a conductive line, and a first connecting member. The first terminal is arranged on a first surface of the substrate. The conductive line is at least partially arranged on a side surface of the substrate and is spaced apart from the first terminal. The first connecting member is connected between the conductive line and the first terminal to make the conductive line electrically connected to the first terminal, and therefore improve electrical connection between the conductive line and the first terminal.

### FIELD OF DISCLOSURE

The present application relates to a field of display technology and in particular, to a display panel, a display device, and a manufacturing method of the display panel.

### DESCRIPTION OF RELATED ART

Due to an increasing demand for narrow bezel and glass splicing technology, there are more and more researches on side metal wiring techniques for a double-sided manufacturing process. At present, a commonly-used side metal wiring technique for the double-sided manufacturing process for display panels is pad printing of silver paste. This leads to poor electrical connection between a conductive line on a side surface of the display panel and a connection terminal on any of two opposite sides of the display panel, resulting in low production yields of the display panel.

### SUMMARY

The present application provides a display panel, a display device, and a manufacturing method of the display panel, which can solve a problem that conductive lines on a side surface of the display panel have poor electrical connection to connection terminals on two opposite sides of the display panel.

The present application provides a display panel, including:

a substrate including a first surface, a second surface, and a side surface, wherein the first surface and the second surface are disposed opposite to each other, and the side surface is disposed between the first surface and the second surface;

a plurality of first terminals disposed on the first surface of the substrate;

a plurality of conductive lines, wherein each conductive line is at least partially disposed on the side surface of the substrate, and the conductive lines are spaced apart from the first terminals; and

a plurality of first connecting members disposed on the substrate, wherein the first connecting members are connected between the conductive lines and the first terminals, so that the conductive lines are electrically connected to the first terminals.

Optionally, in some embodiments of the present application, each first connecting member is at least partially disposed on the first surface, and/or each first connecting member is at least partially disposed on the side surface.

Optionally, in some embodiments of the present application, the display panel further comprises a plurality of second terminals and a plurality of second connecting members, the second terminals are disposed on the second surface of the substrate, the second terminals are spaced apart from the conductive lines, the second connecting members are disposed on the substrate, and the second connecting members are connected between the conductive lines and the second terminals, so that the conductive lines are electrically connected to the second terminals.

Optionally, in some embodiments of the present application, each second connecting member is at least partially disposed on the second surface, and/or each second connecting member is at least partially disposed on the side surface.

Optionally, in some embodiments of the present application, an orthographic projection of each first terminal projected on the substrate at least partially overlaps an orthographic projection of a corresponding one of the second terminals projected on the substrate.

Optionally, in some embodiments of the present application, the first terminals are disposed on the first surface and close to the side surface, and/or the second terminals are disposed on the second surface and close to the side surface.

Optionally, in some embodiments of the present application, the display panel comprises multiple first terminals and multiple conductive lines, the first terminals are disposed in a one-to-one correspondence with the conductive lines, the display panel comprises multiple first connecting members, and each first connecting member is connected between the corresponding first terminal and the corresponding conductive line.

Optionally, in some embodiments of the present application, the display panel comprises multiple second terminals and multiple second connecting members, the second terminals are disposed in a one-to-one correspondence with the conductive lines, and each second connecting member is connected between the corresponding second terminal and the corresponding conductive line.

Optionally, in some embodiments of the present application, the first terminals are arranged side by side on the first surface and close to the side surface; and the second terminals are arranged side by side on the second surface and close to the side surface.

Optionally, in some embodiments of the present application, the display panel further comprises a protective layer covering the first terminals, the second terminals, the conductive lines, the first connecting members, and the second connecting members. Optionally, in some embodiments of the present application, the substrate comprises a

driving circuit layer, a base substrate, and a pixel layer that are sequentially arranged from the second surface toward the first surface, the pixel layer is electrically connected to the first terminals, and the driving circuit layer is electrically connected to the second terminals.

Optionally, in some embodiments of the present application, a material of the first terminals, the second terminals, and the conductive lines comprises one or more of copper, aluminum, molybdenum, or titanium; and a material of the first connecting members and the second connecting members comprises solder paste.

Accordingly, the present application further provides a display device, including the display panel mentioned above.

Accordingly, the present application further provides a manufacturing method of a display panel, including following steps:

providing a substrate, wherein the substrate comprises a first surface, a second surface, and a side surface, the first surface and the second surface are disposed opposite to each other, and the side surface is disposed between the first surface and the second surface;

forming a plurality of first terminals on the first surface of the substrate;

forming a plurality of conductive lines on the side surface of the substrate, wherein the conductive lines are spaced apart from the first terminals; and forming a plurality of first connecting members between the first terminals and the

conductive lines, so that the first terminals are electrically connected to the conductive lines.

Optionally, in some embodiments of the present application, the step of forming the first connecting members between the first terminals and the conductive lines comprises:

using a dispensing process to form solder paste between the first terminals and the conductive lines to form the first connecting members, or using a printing process to form the solder paste between the first terminals and the conductive lines to form the first connecting members.

Optionally, in some embodiments of the present application, the manufacturing method of the display panel further comprises:

forming the second terminals on the second surface of the substrate, such that the second terminals are spaced apart from the conductive lines; and

forming the second connecting members between the second terminals and the conductive lines, so that the second terminals are electrically connected to the conductive lines.

Optionally, in some embodiments of the present application, the step of forming the second connecting members between the second terminals and the conductive lines comprises:

using a dispensing process to form solder paste between the second terminals and the conductive lines to form the second connecting members, or using a printing process to form the solder paste between the second terminals and the conductive lines to form the second connecting members.

Optionally, in some embodiments of the present application, the step of forming the conductive lines on the side surface of the substrate comprises:

attaching a protective layer on the first surface and the second surface, such that the protective layer at least partially covers the first terminals and the second terminals;

depositing a metal layer on the side surface of the substrate;

removing the protective layer; and

processing the metal layer to form the conductive lines.

Optionally, in some embodiments of the present application, the step of forming the conductive lines on the side surface of the substrate comprises:

attaching a protective layer on the first surface and the second surface, such that the protective layer at least partially covers the first terminals and the second terminals;

depositing a metal layer on the side surface of the substrate;

processing the metal layer to form the conductive lines; and

removing the protective layer.

Optionally, in some embodiments of the present application, the manufacturing method of the display panel further comprises:

forming a protective layer on the substrate, such that the protective layer covers the first terminals, the second terminals, the conductive lines, the first connecting members, and the second connecting members. Advantages of the present application:

In the present application, the display panel comprises a substrate, a plurality of first terminals, a plurality of conductive lines, and a plurality of first connecting members. The substrate comprises a first surface, a second surface, and a side surface. The first surface and the second surface are disposed opposite to each other, the first terminals are arranged on the first surface of the substrate, the conductive lines are at least partially arranged on the side surface of the substrate, the conductive lines are spaced apart from the first terminals, and the first connecting members are connected between the conductive lines and the first terminals, so that the conductive lines are electrically connected to the first terminals. In the present application, the conductive lines are arranged on the side surface of the substrate, the conductive lines are spaced apart from the first terminals, and the first connecting members are arranged between the conductive lines and the first terminals, so that the conductive lines are electrically connected to the first terminals through the first connecting members, which can improve electrical connection between the conductive lines and the first terminals and improve production yields of the display panel.

### BRIEF DESCRIPTION OF DRAWINGS

In order to more clearly illustrate the embodiments of the present disclosure or related art, figures which will be described in the embodiments are briefly introduced hereinafter. It is obvious that the drawings are merely for the purposes of illustrating some embodiments of the present disclosure, and a person having ordinary skill in this field can obtain other figures according to these figures without inventive work.

FIG. 1 is a schematic structural view illustrating a display panel according to one embodiment of the present application.

FIG. 2 is a view taken along line A-A of FIG. 1 according to one embodiment of the present application.

FIG. 3 is a schematic structural view illustrating a display device according to one embodiment of the present application.

FIG. 4 is a process flow diagram illustrating a manufacturing method of the display panel according to one embodiment of the present application.

FIG. 5 is a schematic structural view illustrating step 5200 of FIG. 4 according to one embodiment of the present application.

FIG. 6 is a schematic structural view illustrating step 5300 of FIG. 4 according to one embodiment of the present application.

FIG. 7 is a schematic structural view illustrating step 5400 of FIG. 4 according to one embodiment of the present application.

### Description of Reference Numeral:

| Reference | |
|---|---|
| numeral | Part name |
| 10 | Display device |
| 100 | Display panel |
| 110 | Substrate |
| 111 | First surface |
| 112 | Second surface |
| 113 | Driving circuit layer |
| 114 | Base substrate |
| 115 | Pixel layer |
| 120 | First terminal |
| 130 | Second terminal |
| 140 | Conductive line |
| 150 | First connecting member |
| 160 | Second connecting member |
| 170 | Protective layer |
| 200 | Control circuit |
| 300 | housing |

### DETAILED DESCRIPTION OF EMBODIMENTS

The technical solutions in the present application will be clearly and completely described below in conjunction with accompanying drawings and with reference to specific embodiments. Obviously, the embodiments are only some of the embodiments of the present application, rather than all the embodiments. Based on the embodiments in the present application, all other embodiments obtained by those skilled in the art without creative work shall fall within the protection scope of the present application. In addition, it should be understood that the specific embodiments described here are only used to illustrate and explain the present application, and are not used to limit the present application. In the present application, unless otherwise specified, directional terms such as “upper” and “lower” generally refer to the upper and lower directions of a device in actual use or work state, and specifically refer to the directions in the drawings. The terms “inner” and “outer” are referred to with respect to outlines of the device.

The present application provides a display panel, a display device, and a manufacturing method of the display panel. A detailed description is provided below. It should be noted that an order of descriptions in the following embodiments is not intended to limit a preferred order of the embodiments.

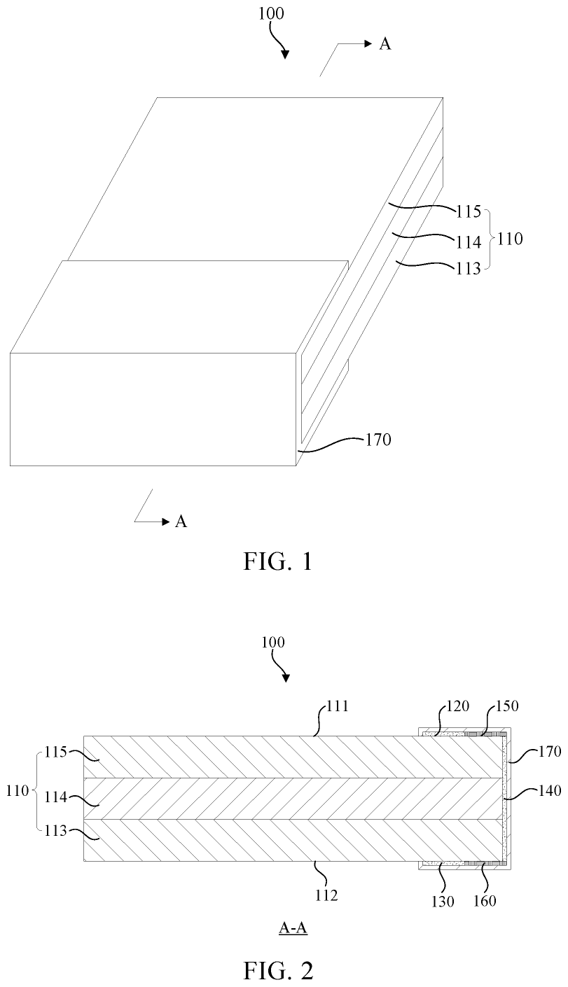

First, the present application provides a display panel. As shown in FIGS. 1 and 2, a display panel 100 comprises a substrate 110. The substrate 110 comprises a first surface 111, a second surface 112, and a side surface. The first surface 111 and the second surface 112 are disposed opposite to each other, and the side surface is disposed between the first surface 111 and the second surface 112. The substrate 110 is used as a supporting structure of the display panel 100 to support other structures in the display panel 100. Further, the substrate 110 can also comprise a functional structure in the display panel 100. The specific functional structure of the substrate 110 can be designed to realize different display needs of the display panel 100.

The display panel 100 comprises a plurality of first terminals 120. The first terminals 120 are disposed on the first surface 111 of the substrate 110. The first terminals 120 are used as a connection end of the first surface 111 of the substrate 110 and are used to connect other structures of the display panel 100 to realize a display control of the display panel 100.

It should be noted that positions of the first terminals 120 on the first surface 111 of the substrate 110 directly affect connection between the first terminals 120 and other structures. The positions of the first terminals 120 can be designed to meet different requirements for structural designs and display functions of the display panel 100.

Optionally, the display panel 100 comprises a plurality of conductive lines 140. Each conductive line 140 is at least partially disposed on the side surface of the substrate 110, and the side surface is connected between the first surface 111 and the second surface 112. That is to say, the conductive lines 140 disposed on the side surface are used to extend a circuit structure on the first surface 111 of the substrate 110 to the second surface 112 of the substrate 110, so as to optimize a circuit structure design on the substrate 110, thereby facilitating the display control of the display panel 100.

The conductive lines 140 are spaced apart from the first terminals 120. That is to say, the conductive lines 140 on the side surface of the substrate 110 are not directly connected to the first terminals 120 on the first surface 111. Such a design allows specific setting positions and structural designs of the first terminals 120 and the conductive lines 140 to be adjusted without interfering with each other according to structural design requirements of the display panel 100, thereby facilitating a more flexible arrangement for the conductive lines 140 and the first terminals 120.

Optionally, the display panel 100 comprises a plurality of first connecting members 150 disposed on the substrate 110. The first connecting member 150 is connected between the conductive line 140 and the first terminal 120, so that the conductive line 140 is electrically connected to the first terminal 120. That is, the first terminal 120 is electrically connected to the conductive line 140 through the first connecting member 150, so as to extend a circuit structure of the first surface 111 of the substrate 110 to the side surface of the substrate 110.

Positions of the first connecting members 150 can be adjusted according to the positions of the first terminals 120 and the conductive lines 140, and it is only necessary to ensure that the first terminals 120 and the conductive lines 140 can be electrically connected through the first connecting members 150. That is to say, the present application allows a more flexible arrangement for the first terminals 120 and the conductive lines 140, which facilitates an overall structural design of the display panel 100.

In the present application, the display panel 100 comprises a substrate 110, a plurality of first terminals 120, a plurality of conductive lines 140, and a plurality of first connecting members 150. The substrate 110 comprises a first surface 111, a second surface 112, and a side surface. The first surface 111 is arranged opposite to the second surface 112, the side surface is arranged between the first surface 111 and the second surface 112, the first terminals 120 are arranged on the first surface 111 of the substrate 110, and the conductive lines 140 are at least partially disposed on the side surface of the substrate 110. The conductive lines 140 are spaced apart from the first terminals 120, and the first connecting members 150 are connected between the conductive lines 140 and the first terminals 120 to make the conductive lines 140 electrically connected to the first terminals 120. In the present application, the conductive lines 140 are arranged on the side surface of the substrate 110, the conductive lines 140 are spaced from the first terminals 120, and the first connecting members 150 are arranged between the conductive lines 140 and the first terminals 120, so that the conductive lines 140 are electrically connected to the first terminals 120 through the first connecting members 150, which can improve electrical connection between the conductive lines 140 and the first terminals 120, and improve production yields of the display panel 100.

Optionally, the first connecting member 150 is at least partially disposed on the first surface 111. That is to say, there is a gap between the first terminal 120 and an edge of the side surface of the substrate 110, so as to facilitate an arrangement for the positions of the first terminals 120. When the first connecting members 150 are entirely disposed on the first surface 111, the conductive lines 140 are entirely disposed on the side surface and extend to an edge connecting the side surface and the first surface 111. Alternatively, each conductive line 140 is partially disposed on the side surface, and partially disposed on the first surface 111 to make the first terminals 120 electrically connected to the conductive lines 140 through the connecting members 150.

In some embodiments, the first connecting member 150 is at least partially disposed on the side surface. That is to say, the conductive lines 140 are entirely located on the side surface, and there is a gap between each conductive line 140 and the edge of the first surface 111 of the substrate 110 to facilitate an arrangement for the positions of the conductive lines 140. When the first connecting members 150 are entirely disposed on the side surface, the first terminals 120 are entirely located on the first surface 111 and extend to the edge of the first surface 111 connecting the side surface. Alternatively, the first terminals 120 are partially disposed on the first surface 111 and partially disposed on the side surface, so that the first connecting members 150 electrically connect the first terminals 120 to the conductive lines 140.

In other embodiments, the first connecting member 150 is partially disposed on the first surface 111 and partially disposed on the side surface. That is to say, there is a gap between the first terminal 120 and the edge of the side surface, and there is a gap between the conductive line 140 and the edge of the first surface 111. In manufacturing the first connecting member 150, it needs to be arranged on the first surface 111 and the side surface at the same time to realize the electrical connection between the first terminal 120 and the conductive line 140. Such a design achieves a more flexible arrangement for the first terminal 120 and the conductive line 140. After the first terminal 120 and the conductive line 140 are disposed according to actual needs, the electrical connection between the first terminal 120 and the conductive line 140 can be realized by simply inserting the first connecting member 150 connected between the first terminal 120 and the conductive line 140.

Optionally, the display panel 100 comprises a plurality of second terminals 130 disposed on the second surface 112 of the substrate 110, wherein the second terminals 130 are used as a connection end of the second surface 112 of the substrate 110 for connecting to other structures of the display panel 100 to realize the display control of the display panel 100.

It should be noted that the position of the second terminal 130 on the second surface 112 of the substrate 110 directly affects a connection between the second terminal 130 and other structures. An arrangement for positions of the second terminals 130 can satisfy different requirements for a structural design and a display function for the display panel 100.

The second terminals 130 are spaced apart from the conductive lines 140. That is to say, the conductive lines 140 on the side surface of the substrate 110 are not directly connected to the second terminals 130 on the second surface 112. Such a design allows specific positions and structures of the second terminals 130 and the conductive lines 140 to be adjusted, without interfering with each other, according to the structural requirements of the display panel 100, thereby realizing a more flexible arrangement for the conductive lines 140 and the second terminals 130.

The display panel 100 further comprises a plurality of second connecting members 160. The second connecting members 160 are disposed on the substrate 110, and the second connecting member 160 is connected between the conductive line 140 and the second terminal 130, so that the conductive line 140 is electrically connected to the second terminal 130. That is to say, the second terminal 130 is electrically connected to the conductive line 140 through the second connecting member 160, so that the circuit structure of the first surface 111 of the substrate 110 is connected to the side surface of the substrate 110, and then to the second surface 112 of the substrate 110. Thus, the present application realizes a display control on the first surface 111 of the substrate 110 through the second surface 112 of the substrate 110.

The position of the second connecting member 160 can be adjusted according to the positions of the second terminal 130 and the conductive line 140, and it is only necessary to ensure that the second terminal 130 and the conductive line 140 can be electrically connected through the second connecting member 160. Accordingly, the present application allows a more flexible arrangement for the second terminals 130 and the conductive lines 140, which facilitates the overall structural design of the display panel 100.

Optionally, the second connecting member 160 is at least partially disposed on the second surface 112. That is to say, there is a gap between the second terminal 130 and the edge of the side surface of the substrate 110. Alternatively, the second connecting member 160 is at least partially disposed on the side surface. That is to say, the conductive line 140 is entirely disposed on the side surface, and there is a gap between the conductive line 140 and the edge of the second surface 112 of the substrate 110. Alternatively, the second connecting member 160 is partially disposed on the second surface 112 and partially disposed on the side surface. That is to say, there is a gap between the second terminal 130 and the edge of the side surface, and there is a gap between the conductive line 140 and the edge of the second surface 112, so that the second connecting member 160 can electrically connect the second terminal 130 to the conductive line 140.

The arrangement of the second connecting member 160 on the second surface 112 and on the side surface can refer to the above description about the arrangement of the first connecting member 150 on the first surface 111 and on the side surface, and it is only necessary to ensure the effective electrical connection between the second terminal 130 and the conductive line 140 through the second connecting member 160. A detailed description is repeated for brevity.

Optionally, an orthographic projection of the first terminal 120 projected on the substrate 110 at least partially overlaps an orthographic projection of the second terminal 130 projected on the substrate 110. That is to say, the first terminal 120 and the second terminal 130 are disposed on two opposite sides of the substrate 110. Such a design facilitates arranging the first terminal 120 and the second terminal 130 opposite to each other, thereby facilitating a layout design of the conductive lines 140 on the side surface.

In some embodiments, the orthographic projection of the first terminal 120 projected on the substrate 110 completely coincides with the orthographic projection of the second terminal 130 on the substrate 110. That is to say, the first terminal 120 and the second terminal 130 have the same structure and are symmetrically arranged on two opposite sides of the substrate 110. Such a design can further simplify the arrangement of the conductive lines 140 on the side surface and improve production efficiency of the display panel 100.

Optionally, the first terminal 120 is disposed on the first surface 111 close to the side surface. That is to say, the first terminal 120 is close to the edge connecting the first surface 111 and the side surface, so that the first terminal 120 can be electrically connected to the conductive line 140. In addition to that, by arranging the first terminal 120 close to the edge connecting the first surface 111 and the side surface, the present application can reduce lengths of the conductive line 140 and the first connecting member 150, thereby reducing a length of a wiring between the first surface 111 and the side surface, and reducing overall resistance of this wiring, which is beneficial to improve display performance of the display panel 100.

Optionally, the second terminal 130 is disposed on the second surface 112 close to the side surface. That is to say, the second terminal 130 is close to the edge connecting the second surface 112 and the side surface, so that the second terminal 130 is electrically connected to the conductive line 140 on the side surface. In addition to that, by arranging the second terminal 130 close to the edge connecting the second surface 112 and the side surface, the present application can reduce lengths of the conductive line 140 and the second connecting member 160, thereby reducing a length of a wiring between the side surface and the second surface 112, and reducing overall resistance of this wiring, which is beneficial to improve the display performance of the display panel 100.

In some embodiments, the first terminal 120 is disposed on the first surface 111 close to the side surface, and the second terminal 130 is disposed on the second surface 112 close to the side surface. That is to say, the first terminal 120 and the second terminal 130 are located close to the edges of the side surface, thereby reducing lengths of the first connecting member 150, the second connecting member 160, and the conductive line 140, and further reducing an overall length of a wiring from the first surface 111 to the second surface 112, which is beneficial to control a display mode of the display panel 100 and improve the display performance of the display panel 100.

Optionally, the display panel 100 comprises multiple first terminals 120 and multiple conductive lines 140, and the first terminals 120 and the conductive lines 140 are arranged in a one-to-one correspondence. The display panel 100 comprises multiple first connecting members 150. Each of the first connecting members 150 is connected between the corresponding first terminal 120 and the corresponding conductive line 140, so that the first terminals 120 and the conductive lines 140 are electrically connected in a one-to-one correspondence, so as to realize individual control of an area corresponding to each first terminal 120 and achieve different display requirements of the display panel 100.

The first terminals 120 are arranged side by side on the first surface 111 close to the side surface, and the conductive lines 140 are arranged side by side on the side surface, so as to facilitate the electrical connection between the first terminals 120 and the respective corresponding conductive lines 140 and simplify a wring design of the conductive lines 140 on the side surface.

Optionally, the display panel 100 comprises multiple second terminals 130 and multiple second connecting members 160. The second terminals 130 and the conductive lines 140 are arranged in a one-to-one correspondence. The second connecting members 160 are connected between the second terminals 130 and the conductive lines 140, so that the second terminals 130 and the conductive lines 140 are electrically connected in a one-to-one correspondence, so as to realize the one-to-one electrical connection between the second terminals 130 and the first terminals 120. Accordingly, the present application facilitates configuration of a driving circuit on the display panel 100, and controls a display mode of the first surface 111 of the substrate 110 through the second surface 112 of the substrate 110, so as to meet different display requirements of the display panel 100.

The second terminals 130 are arranged side by side on the second surface 112 close to the side surface, and the conductive lines 140 are arranged side by side on the side surface, so as to facilitate the electrical connection between the second terminals 130 and the respective corresponding conductive lines 140, and simplify the wiring design of the conductive lines 140 on the side surface.

It should be noted that the second terminals 130 and the first terminals 120 are disposed in a one-to-one correspondence on opposite sides of the substrate 110, so as to facilitate the conductive lines 140 electrically connected to the respective corresponding first terminals 120 and the respective corresponding second terminals 130, simplify the layout design of the conductive lines 140 on the side surface, reduce the overall resistance of the wiring from the first surface 111 to the second surface 112, and improve the display performance of the display panel 100.

Optionally, the display panel 100 further comprises a protective layer 170. The protective layer 170 covers the first terminals 120, the second terminals 130, the conductive lines 140, the first connecting members 150, and the second connecting members 160. That is to say, the protective layer 170 covers a circuit structure on the substrate 110 to protect the circuit structure and to prevent malfunction of the display panel 100 due to damage to the circuit structure during manufacture or use of the display panel 100. Accordingly, the present application improves stability of the display panel 100. In addition, the protective layer 170 can also planarize a surface of the display panel 100 and improve an overall appearance of the display panel 100.

In some embodiments, the substrate 110 comprises a driving circuit layer 113, a base substrate 114, and a pixel layer 115 arranged in sequence from the second surface 112 toward the first surface 111. The pixel layer 115 is electrically connected to the first terminal 120 and the driving circuit layer 113 is electrically connected to the second terminal 130. That is to say, the first terminal 120 is an electrical connection point of the pixel layer 115, and the second terminal 130 is an electrical connection point of the driving circuit layer 113. By electrically connecting the first terminal 120 to the second terminal 130 through the first connecting member 150, the conductive line 140, and the second connecting member 160, the present application realizes the electrical connection between the pixel layer 115 and the driving circuit layer 113, so as to use the driving circuit of the second surface 112 to control the pixels of the first surface 111, thus optimizing the overall structural design of the display panel 100 to meet different display requirements of the display panel 100.

In other embodiments, the substrate 110 comprises a pixel layer 115, a base substrate 114 and a driving circuit layer 113 arranged in sequence from the second surface 112 toward the first surface 111. The pixel layer 115 is electrically connected to the second terminal 130, and the driving circuit layer 113 is electrically connected to the first terminal 120. That is, positions of the pixel layer 115 and the driving circuit layer 113 are interchanged. The first terminal 120 is an electrical connection point of the driving circuit layer 113, and the second terminal 130 is an electrical connection point of the pixel layer 115. Accordingly, the present application also optimizes the whole structural design of the display panel 100. The specific configuration can be adjusted according to the actual structural design requirements of the display panel 100, which is not particularly limited here.

It should be noted that the pixel layer 115 comprises multiple pixels, the pixels are arranged side by side on the base substrate 114, the pixels are connected to the first terminals 120 in a one-to-one correspondence, and the driving circuit layer 113 comprises multiple driving circuits. The driving circuits are connected to the second terminals 130 in a one-to-one correspondence. By electrically connecting the pixels with the driving circuits in a one-to-one correspondence, the display modes of the pixels on the display panel 100 can be controlled individually, so as to meet different display requirements of the display panel 100.

Optionally, the first terminal 120, the second terminal 130, and the conductive line 140 in the present application can be made of a same material as a material of the metal layer in the display panel 100, wherein the material comprises one or more of copper, aluminum, molybdenum, or titanium, so as to ensure the electrical connection between the first terminal 120 and the conductive line 140 and the electrical connection between the second terminal 130 and the conductive line 140.

The first terminal 120, the second terminal 130, and the conductive line 140 can be made of the same or different materials. The specific materials can be selected according to the actual design requirements, and the present application is not limited in this regard. It is only necessary to ensure that the first terminal 120, the second terminal 130, and the conductive line 140 are electrically connected to each other.

Optionally, the material of the first connecting member 150 and the second connecting member 160 comprises solder paste. The solder paste is a material containing a conductive metal and having conductivity, so as to electrically connect the first terminal 120 to the conductive line 140 and electrically connect the second terminal 130 to the conductive line 140. Using solder paste to produce the first connecting member 150 and the second connecting member 160 can adjust the formation of the first connecting member 150 and the second connecting member 160, so as to improve the electrical connection between the first terminal 120 and the conductive line and the electrical connection between the second terminal 130 and the conductive lines 140.

Secondly, the present application further provides a display device. The display device comprises a display panel, and the specific structure of the display panel is described in the above-mentioned embodiments. Since the display device adopts all the technical solutions of all the above-mentioned embodiments, it has at least all the advantages of the technical solutions of the above embodiments, and a description thereof is not repeated here.

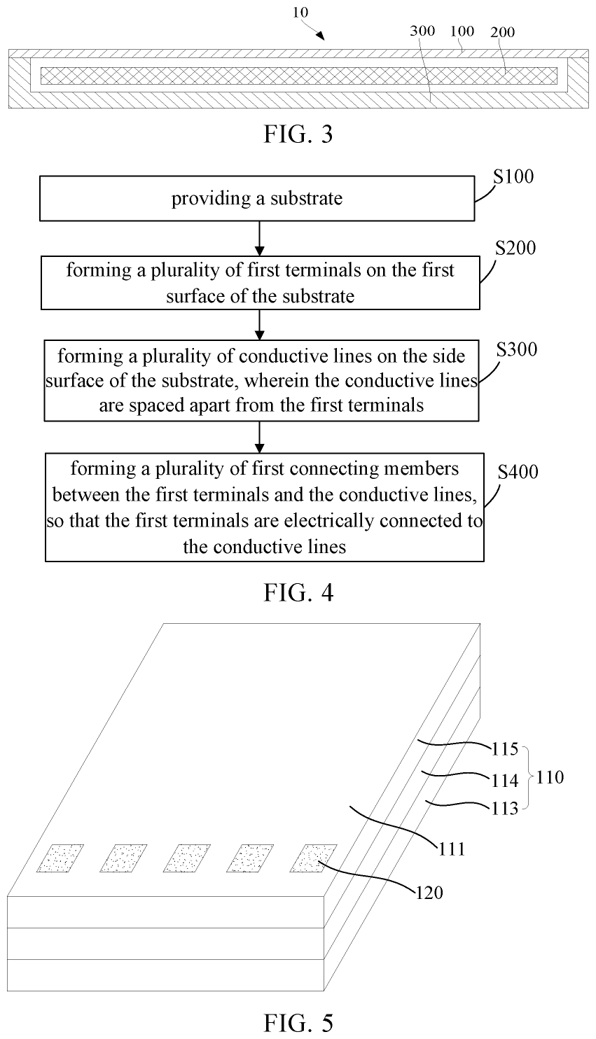

FIG. 3 is a schematic structural view of the display device according to one embodiment of the present application. As shown in FIG. 3, the display device 10 comprises a display panel 100, a control circuit 200, and a housing 300. The housing 300 is connected to the display panel 100 to support and fasten the display panel 100. The control circuit 200 is arranged in the housing 300 and is electrically connected to the display panel 100 to control the display panel 100 to display images.

The display panel 100 can be fixed to the housing 300 to form an integral form with the casing 300. The display panel 100 and the housing 300 form a closed space for accommodating the control circuit 200. The control circuit 200 can be a motherboard of the display device 10. Also, the control circuit 200 can also integrate one or more of a battery, an antenna structure, a microphone, a speaker, a headphone jack, a universal serial bus interface, a camera, a distance sensor, an ambient light sensor, a receiver, a processor, or other functional component, so that the display device 10 can be adapted to various applications.

It should be noted that the display device 10 is not limited to the above descriptions, and can also comprise other components, such as a camera, an antenna structure, and a fingerprint unlocking module, to expand its use range, which is not limited here. The display device 10 of the present application has a wide range of applications, including televisions, computers, flexible displays like foldable or rollable display screens, and lighting, etc., which all fall within the protection scope of the display device 10 of the present application.

Finally, the present application also provides a manufacturing method of a display panel. As shown in FIG. 4, the manufacturing method of the display panel 100 comprises the following steps:

S100: providing a substrate 110. The substrate 110 comprises a first surface 111, a second surface 112, and a side surface. The first surface 111 and the second surface 112 are arranged opposite to each other, and the side surface is arranged between the first surface 111 and the second surface 112. The substrate 110 is used as a supporting structure of the display panel 100 to support other structures in the display panel 100. Moreover, the substrate 110 can also include functional structures in the display panel 100, and different display requirements of the display panel 100 can be met by the specific structural design of the substrate 110.

S200: forming a plurality of first terminals 120 on the first surface 111 of the substrate 110. As shown in FIG. 5, the first terminal 120 is an electrical connection point of the functional structure on the first surface 111 of the substrate 110, and is used for electrical connection with other structures, so as to control the functional structure on the first surface 111.

It should be noted that a position of the first terminal 120 on the first surface 111 of the substrate 110 directly affects a connection between the first terminal 120 and other structure. Different structural designs and display requirements of the display panel 100 can be met by designing the positions of the first terminals 120.

The first terminal 120 can be disposed on the first surface 111 and close to the side surface. That is to say, the first terminal 120 is located at an edge of the first surface 111 connecting the side surface, so as to establish the electrical connection between the first terminal 120 and other structure. In addition, by arranging the first terminal 120 at the edge of the first surface 111, the present application can also prevent the first terminal 120 from affecting an overall display screen of the display panel 100 and can improve display performance of the display panel 100.

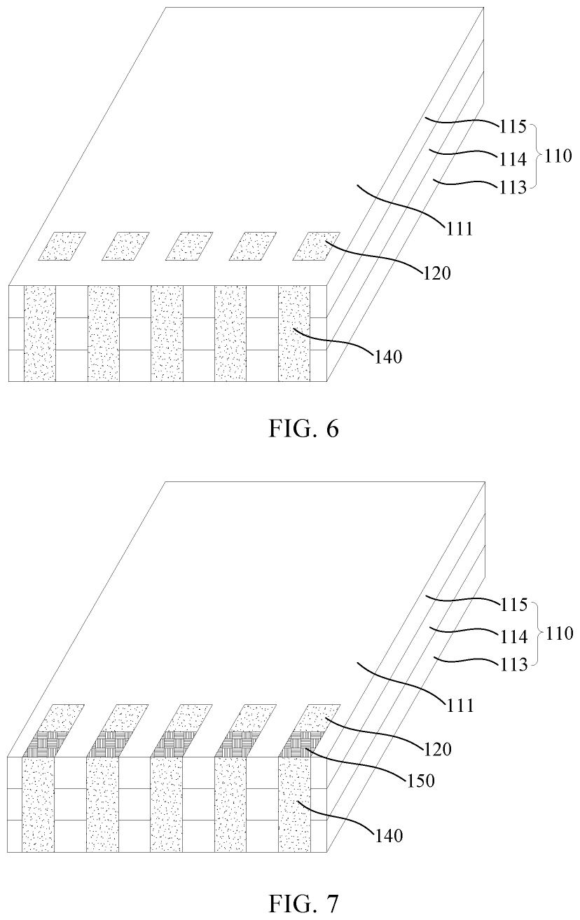

S300: forming a plurality of conductive lines 140 on the side surface of the substrate 110, such that the conductive lines 140 are spaced from the first terminals 120. As shown in FIG. 6, the side surface is connected between the first surface 111 and the second surface 112. That is to say, the conductive lines 140 arranged on the side surface are used to extend the circuit structure of the first surface 111 of the substrate 110 to the second surface 112 of the substrate 110, thereby allowing for an optimal circuit structure design on the substrate 110 and facilitating controlling display modes of the display panel 100.

The conductive lines 140 are spaced apart from the first terminals 120. That is to say, the conductive lines 140 on the side surface of the substrate 110 are not directly connected to the first terminals 120 on the first surface 111. Such a design allows specific positions and design structures of the first terminals 120 and the conductive lines 140 to be adjusted without interfering with each other according to structural design requirements of the display panel 100, thereby facilitating a more flexible arrangement for the conductive lines 140 and the first terminals 120.

S400: forming a plurality of first connecting members 150 between the first terminals 120 and the conductive lines 140, so that the first terminals 120 are electrically connected to the conductive lines 140. That is to say, the first terminals 120 are electrically connected to the conductive lines 140 through the first connecting members 150, so as to extend the circuit structure of the first surface 111 of the substrate 110 to the side surface of the substrate 110.

As shown in FIG. 7, positions of the first connecting members 150 can be adjusted according to positions of the first terminals 120 and the conductive lines 140, and it is only necessary to ensure that the first terminals 120 can be electrically connected to the conductive lines 140 through the first connecting members 150. Accordingly, the present application allows a more flexible arrangement for the first terminals 120 and the conductive lines 140, which facilitates the overall structural design of the display panel 100.

Optionally, the first connecting member 150 can be a conductive material such as solder paste. In some embodiments, solder paste is formed between the first terminals 120 and the conductive lines 140 by using a dispensing process to form the first connecting members 150. The use of the dispensing process makes the first connecting members 150 have a more flexible formation method and structure. Furthermore, the positions of the first connecting members 150 can be adjusted as desired according to the positions of the first terminals 120 and the conductive lines 140, which allows for easy repair of the circuit between the first terminals 120 and the conductive lines 140.

In other embodiments, solder paste is formed between the first terminals 120 and the conductive lines 140 by a printing process to form the first connecting members 150. According to the relative positions of the first terminals 120 and the conductive lines 140, a layer of solder paste is printed between the first terminals 120 and the conductive lines 140, so as to realize the electrical conduction between the first terminals 120 and the conductive lines 140. Compared with the conventional patterning techniques, the present application improves connection stability between the first terminals 120 and the conductive lines 140.

Optionally, the manufacturing method of the display panel 100 of the present application further comprises following steps: forming a plurality of second terminals 130 on the second surface 112 of the substrate 110, so that the second terminals 130 are spaced apart from the conductive lines 140. A plurality of second connecting members 160 are formed between the second terminals 130 and the conductive lines 140, so that the second terminals 130 are electrically connected to the conductive lines 140.

In some embodiments, solder paste is formed between the second terminals 130 and the conductive lines 140 by using a dispensing process to form the second connecting members 160. The use of the dispensing process makes the second connecting members 160 have a more flexible formation method, structural design, and position arrangement, and also facilitates easy repair of the circuit between the second terminals 130 and the conductive lines 140.

In other embodiments, solder paste is formed between the second terminals 130 and the conductive lines 140 by using a printing process to form the second connecting members 160. Compared with conventional patterning processes, a layer of solder paste is printed between the second terminals 130 and the conductive lines 140 to realize the electrical conduction between the second terminals 130 and the conductive lines 140, which can improve the connection stability between the second terminals 130 and the conductive lines 140.

In actual manufacturing of the display panel 100, the first terminals 120 and the second terminals 130 can be formed on the first surface 111 and the second surface 112 of the substrate 110, respectively, and then the conductive lines 140 are formed on the side surface, wherein the two ends of the conductive line 140 are spaced apart from the first terminal 120 and the second terminal 130. Finally, the first connecting member 150 is formed between the first terminal 120 and the conductive line 140, and the second connecting member 150 is formed between the second terminal 130 and the conductive line 140, so as to realize the electrical connection between the first terminal 120 and the second terminal 130.

It should be noted that the embodiments of the present application only describe each step, but a specific formation sequence is not particularly limited. It only needs to ensure the effective electrical connection between the first terminal 120 and the second terminal 130 through the first connecting member 150 and the conductive line 140 and the second connecting member 160.

In some embodiments, forming the conductive lines 140 on the side surface of the substrate 110 in step S300 mainly comprises following steps:

First, a protective film is attached to the first surface 111 and the second surface 112, so that the protective film at least partially covers the first terminal 120 and the second terminal 130. Next, a metal layer is deposited on the side surface of the substrate 110. Then, the protective film is removed. Finally, the metal layer is processed to form the conductive lines 140.

By attaching the protective film to the first surface 111 and the second surface 112, the first terminal 120 and the second terminal 130 are protected, so as to prevent the metal layer from covering the first terminals 120 and the second terminals 130 resulting from a deposition angle problem during a process of depositing the metal layer on the side surface, which is not conducive to the subsequent arrangement of the conductive lines 140, even leads to crosstalk between two adjacent first terminals 120, and affects the control of the display mode of the display panel 100.

It should be noted that the protective film can partially cover the first terminals 120 and the second terminals 130. That is to say, the first terminals 120 and the second terminals 130 are partially exposed. Therefore, when the metal layer is deposited, a portion of the metal layer is connected to the first terminals 120 and the second terminals 130. When the protective film is removed, the connected portion of the metal layer can be peeled off, so that the first terminal 120 and the second terminal 130 are disconnected from the metal layer.

Alternatively, the protective film directly covers the first terminal 120 and the second terminal 130 completely. Therefore, in the process of depositing the metal layer, the metal layer is directly disconnected from the first terminal 120 and the second terminal 130, which is beneficial to the subsequent processing of the metal layer to form the conductive lines 140, thus preventing crosstalk between adjacent first terminals 120 or second terminals 130.

The protective film can be a polyimide film or other release film, and it is only necessary to ensure that the protective film can protect the first terminal 120 and the second terminal 130 during the process of forming the conductive line 140, and is easy to remove without residue remained on the substrate 100 after the conductive line 140 is formed. The present application is not limited in this regard.

Optionally, a metal layer can be deposited on the side surface of the substrate 110 by means of physical deposition, chemical deposition, or spraying, so that the metal layer covers the entire side surface of the substrate 110. Then, the metal layer is processed by means of laser, dry etching, or wet etching, so as to form a plurality of conductive lines 140 arranged at intervals on the side surface of the substrate 110.

The conductive lines 140 can be in any shape such as straight lines, folded lines or curves. The arrangement and specific structure of the conductive lines 140 can be adjusted through the laser or etching process according to the actual design requirements. It is only necessary to ensure electrical conduction between the conductive line 140 and the first terminal 120 and between the conductive line 140 and the second terminal 130.

In other embodiments, the step 5300 of forming the conductive line 140 on the side surface of the substrate 110 mainly comprises following steps:

First, a protective film is attached to the first surface 111 and the second surface 112, such that the protective film at least partially covers the first terminal 120 and the second terminal 130. Next, a metal layer is deposited on the side surface of the substrate 110. Then, the metal layer is processed to form conductive lines 140. Finally, the protective film is removed.

In the manufacturing method, the conductive lines 140 are formed first, and then the protective film are removed. Therefore, during the process of processing the metal layer, the protective film can still protect the first terminal 120 and the second terminal 130 to prevent impurities generated during the processing of the metal layer from accumulating on surfaces of the first terminal 120 and the second terminal 130 or between the adjacent two first terminals 120 or second terminal 130, which affects the electrical connection between the first connecting member 150 and the first terminal 120 or between the second connecting member 160 and the second terminal 130 and affects the control over the display mode of the display panel 100.

Optionally, the manufacturing method of the display panel 100 of the present application further comprises: forming a protective layer 170 on the substrate 110, such that the protective layer 170 covers the first terminals 120, the second terminals 130, the conductive lines 140, the first connecting members 150, and the second connecting members 160.

After the circuit structure is formed on the first surface 111, the second surface 112, and the side surface of the substrate 110, the protective layer 170 needs to be formed on the substrate 110 to protect the circuit structure and prevent the display panel 100 from malfunction due to damage to the circuit structure during fabrication or use of the display panel 100, thereby improving the stability of the display panel 100. Moreover, the protective layer 170 can also planarize the surface of the display panel 100 and improve the overall appearance of the display panel 100.

The above describes in detail the display panel, the display device, and the manufacturing method of the display panel according to the embodiments of the present application. Specific examples are used in the present disclosure to illustrate working principles and embodiments of the present application. The description of the above embodiments is only for ease of understanding the method and main ideas of the present application. According to the idea of the present application, those skilled in the art can change the embodiments and the range of application. In summary, the content of this specification should not be construed as a limitation to the present application.

What is claimed is:

1. A display panel, comprising:
a substrate comprising a first surface, a second surface, and a side surface, wherein the first surface and the second surface are disposed opposite to each other, and the side surface is disposed between the first surface and the second surface;
a plurality of first terminals disposed on the first surface of the substrate;
a plurality of conductive lines, wherein each conductive line is at least partially disposed on the side surface of the substrate, and the conductive lines are spaced apart from the first terminals; and
a plurality of first connecting members disposed on the substrate, wherein the first connecting members are connected between the conductive lines and the first terminals, so that the conductive lines are electrically connected to the first terminals.

2. The display panel according to claim 1, wherein each first connecting member is at least partially disposed on the first surface, and/or each first connecting member is at least partially disposed on the side surface.

3. The display panel according to claim 1, further comprising a plurality of second terminals and a plurality of second connecting members, wherein the second terminals are disposed on the second surface of the substrate, the second terminals are spaced apart from the conductive lines, the second connecting members are disposed on the substrate, and the second connecting members are connected between the conductive lines and the second terminals, so that the conductive lines are electrically connected to the second terminals.

4. The display panel according to claim 3, wherein each second connecting member is at least partially disposed on the second surface, and/or each second connecting member is at least partially disposed on the side surface.

5. The display panel according to claim 3, wherein an orthographic projection of each first terminal projected on the substrate at least partially overlaps an orthographic projection of a corresponding one of the second terminals projected on the substrate.

6. The display panel according to claim 3, wherein the first terminals are disposed on the first surface and close to the side surface, and/or the second terminals are disposed on the second surface and close to the side surface.

7. The display panel according to claim 3, wherein the display panel comprises multiple first terminals and multiple conductive lines, the first terminals are disposed in a one-to-one correspondence with the conductive lines, the display panel comprises multiple first connecting members, and each first connecting member is connected between the corresponding first terminal and the corresponding conductive line.

8. The display panel according to claim 7, wherein the display panel comprises multiple second terminals and multiple second connecting members, the second terminals are disposed in a one-to-one correspondence with the conductive lines, and each second connecting member is connected between the corresponding second terminal and the corresponding conductive line.

9. The display panel according to claim 8, wherein the first terminals are arranged side by side on the first surface and close to the side surface; and the second terminals are arranged side by side on the second surface and close to the side surface.

10. The display panel according to claim 3, wherein the display panel further comprises a protective layer covering the first terminals, the second terminals, the conductive lines, the first connecting members, and the second connecting members.

11. The display panel according to claim 3, wherein the substrate comprises a driving circuit layer, a base substrate, and a pixel layer that are sequentially arranged from the second surface toward the first surface, the pixel layer is electrically connected to the first terminals, and the driving circuit layer is electrically connected to the second terminals.

12. The display panel according to claim 3, wherein a material of the first terminals, the second terminals, and the conductive lines comprises one or more of copper, aluminum, molybdenum, or titanium; and a material of the first connecting members and the second connecting members comprises solder paste.

13. A display device, comprising the display panel of claim 1.

14. A manufacturing method of a display panel, comprising following steps:
providing a substrate, wherein the substrate comprises a first surface, a second surface, and a side surface, the first surface and the second surface are disposed opposite to each other, and the side surface is disposed between the first surface and the second surface;
forming a plurality of first terminals on the first surface of the substrate;
forming a plurality of conductive lines on the side surface of the substrate, wherein the conductive lines are spaced apart from the first terminals; and
forming a plurality of first connecting members between the first terminals and the conductive lines, so that the first terminals are electrically connected to the conductive lines.

15. The manufacturing method of the display panel according to claim 14, wherein the step of forming the first connecting members between the first terminals and the conductive lines comprises:
using a dispensing process to form solder paste between the first terminals and the conductive lines to form the first connecting members, or using a printing process to form the solder paste between the first terminals and the conductive lines to form the first connecting members.

16. The manufacturing method of the display panel according to claim 14, further comprising:
forming the second terminals on the second surface of the substrate, such that the second terminals are spaced apart from the conductive lines; and forming the second connecting members between the second terminals and the conductive lines, so that the second terminals are electrically connected to the conductive lines.

17. The manufacturing method of the display panel according to claim 16, wherein the step of forming the second connecting members between the second terminals and the conductive lines comprises:
using a dispensing process to form solder paste between the second terminals and the conductive lines to form the second connecting members, or using a printing process to form the solder paste between the second terminals and the conductive lines to form the second connecting members.

18. The manufacturing method of the display panel according to claim 16, wherein the step of forming the conductive lines on the side surface of the substrate comprises:
attaching a protective layer on the first surface and the second surface, such that the protective layer at least partially covers the first terminals and the second terminals;
depositing a metal layer on the side surface of the substrate;
removing the protective layer; and
processing the metal layer to form the conductive lines.

19. The manufacturing method of the display panel according to claim 16, wherein the step of forming the conductive lines on the side surface of the substrate comprises:
attaching a protective layer on the first surface and the second surface, such that the protective layer at least partially covers the first terminals and the second terminals;
depositing a metal layer on the side surface of the substrate; processing the metal layer to form the conductive lines; and
removing the protective layer.

20. The manufacturing method of the display panel according to claim 16, further comprising:
forming a protective layer on the substrate, such that the protective layer covers the first terminals, the second terminals, the conductive lines, the first connecting members, and the second connecting members.
